(19) United States
(12) Patent Application Publication
(10) Pub. No.: US 2010/0193869 A1
(43) Pub. Date: Aug. 5, 2010

(54) Semiconductor device having electro-static discharge protection element

(75) Inventor: Tadayuki Habasaki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/656,483

(22) Filed: Feb. 1, 2010

(30) Foreign Application Priority Data
Feb. 3, 2009 (JP) 2009-022534

(51) Int. Cl. H01L 27/06

(52) U.S. Cl. 257/360; 257/E27.016

(57) ABSTRACT

A semiconductor device includes a semiconductor substrate of a first conductivity-type, a buried diffusion layer of a second conductivity-type formed in the semiconductor substrate, a first well of the second conductivity-type having a bottom portion in contact with a top portion of the buried diffusion layer, the first well having an annular shape in a planar view, and a second well of the first conductivity-type formed to be surrounded by the first well. The semiconductor device further includes a diffusion region formed between a first portion of the second well and a second portion of the second well, the diffusion region having an impurity concentration lower than that of the second well, so that a depletion layer formed in the diffusion region can be provided, a transistor formed on the second well to function as an ESD (electro-static discharge) protection element, and an external terminal connected to a drain of the transistor.

### INCORPORATION BY REFERENCE

This application is based upon and claims the benefit of priority from Japanese Patent Application No. 2009-022534 which was filed on Feb. 3, 2009, the disclosure of which is incorporated herein in its entirety by reference.

### BACKGROUND OF THE INVENTION

1. Field of the Invention

The present invention relates to a semiconductor device, and particularly to a semiconductor device including a protection circuit configured to protect the semiconductor device from destruction which would otherwise occur due to ESD (Electro-Static Discharge).

2. Description of Related Art

An internal circuit of a semiconductor device is likely to break down, when static electricity comes into the semiconductor device in a manufacturing process, an inspection process, or a step of incorporating the semiconductor device into an electronic appliance. Thus, a protection circuit configured to protect the semiconductor device from destruction which would otherwise occur due to ESD is installed in an input/output section between the semiconductor device and its outside (see Patent Documents 1 to 5, for instance).

Patent Document 1 has proposed a structure of a protection circuit which allows a protection element to operate more easily by blocking electrons, which occur from the protection element, from diffusing into an internal element by use of an N type buried diffusion layer without increasing its pattern area. FIG. 11 shows a cross-sectional view of a semiconductor device which includes the protection circuit disclosed in Patent Document 1. The semiconductor device 200 includes a protection diode, a protection bipolar transistor and a protection NMOSFET. As shown in FIG. 11, these elements are formed in the inside or surface of a P type well 112 which is separated from a P type semiconductor substrate 101 by N type wells 122 and an N type buried diffusion layer 123.

The protection diode is a PN diode made of a P type diffusion layer 111b and an N type diffusion layer 121b. The P type diffusion layer 111b is connected to a ground wire through an upper layer interconnection 106a. The N type diffusion layer 121b is connected to an input/output terminal (not illustrated) through an aluminum interconnection 106b.

The protection bipolar transistor is an NPN bipolar transistor, which includes a P type well 112 as its base, the N type diffusion layer 121b as its collector; and an N type diffusion layer 121c as its emitter. The N type diffusion layer 121b is the collector region for the transistor, and is connected to the input/output terminal (not illustrated) through the aluminum interconnection 106b. In addition, the N type diffusion layer 121c is the emitter region for the transistor, and is connected to the ground wire (not illustrated) through an aluminum interconnection 106c.

As shown in FIG. 11, the protection NMOSFET is an N type LDDMOSFET, which includes the N type diffusion layers (121c, 121d) formed in the surface of the P type well 112, and a gate electrode 103 formed on the surface of the P type well 112. The N type diffusion, layer 121c is the source region for the transistor, and is connected to the ground wire through the aluminum interconnection 106c. In addition, the N type diffusion layer 121d is the drain region for the transistor, and is connected to the input/output terminal (not illustrated) via an input resistor (not illustrated) through an aluminum interconnection 106d.

Patent Document 2 has proposed a structure of a protection circuit which has a larger parasitic resistance without increasing its pattern area. FIG. 12 shows a schematic cross-sectional view of a semiconductor device which includes the protection circuit disclosed in Patent Document 2. The semiconductor device 300 includes four transistors 255. The four transistors 255 are arranged within a first P type well 212a, which is formed on a P type semiconductor substrate 201. A second P type well 212b is formed around the first P type well 212a with a predetermined gap in between. A P⁺ type diffusion region 211a is configured to function as a guard ring, and is formed within the region of the second P type well 212b in a way as to surround the four transistors 255. A P type low-concentration region 213 has an impurity concentration lower than those of the P type wells 212a, 212b, and is left under a field oxide film 202 inside the P⁺ type diffusion region 211a configured to function as the guard ring.

The drain of each transistor 255 is connected to a pad (not illustrated) and an internal circuit (not illustrated) through an interconnection layer 206a. The source of each transistor 255 is connected to a GND (not illustrated) through an interconnection layer 206b. The gate of each transistor 255 is also connected to the GND.

An NPN type parasitic transistor 252 is formed in an area corresponding to one of the transistors 255 which is adjacent to the P⁺ type diffusion region 211a. The NPN type parasitic transistor 252 includes a collector corresponding to the drain of the transistor 255, an emitter corresponding to the source of the transistor 255, and a base corresponding to the first P type well 212a. A parasitic resistance 253 is formed between the base and the P⁺ type diffusion region 211a. In other words, the parasitic resistance 253 is formed by the first P type well 212a, the P type low-concentration region 213 and the second P type well 212b.

When an ESD surge is applied to the pad (not illustrated), the surge is transmitted to the drain through the interconnection layer 206a, and is broken down in a boundary between the drain diffusion region and the first P type well 212a. Thereby, the ESD surge flows to the GND through the parasitic resistance 253, that is to say, from the first P type well 212a through the P type low-concentration region 213, the second P type well 212b and the P⁺ type diffusion region 211a.

When a current flows due to the ESD surge, a voltage occurs in the parasitic resistance 253. When the base voltage of the parasitic transistor 252 exceeds a threshold voltage VBE (base-emitter voltage), a current flows through the parasitic transistor 252. This makes it possible to suppress the collector voltage in a way that the collector voltage is not larger than a certain value. In other words, the protection element prevents the ESD surge from being transmitted into the internal circuit.

### [Patent Document 1] Japanese Patent No. 3161508

[Patent Document 2] Japanese Patent Application Laid Open No. Hei 11-274404
[Patent Document 3] Japanese Patent Application Laid Open No. Hei 11-274319

### [Patent Document 4] Japanese Patent Application Laid Open No. 2003-78021

### [Patent Document 5] Japanese Patent Application Laid Open No. 2005-520349

### SUMMARY

In recent years, as elements included in a semiconductor integrated circuit have become progressively miniaturized, the ESD breakdown resistance has become lower. With this taken into consideration, a strong demand is placed for a technology which makes it possible to increase the ESD breakdown resistance while achieving miniaturization of the elements.

A semiconductor device of a first exemplary aspect includes a semiconductor substrate of a first conductivity-type, a first conductivity-type well formed in the semiconductor substrate, the first conductivity-type well being a region where an N channel transistor configured to function as the ESD protection element is formed, a second conductivity-type well and a second conductivity-type buried diffusion layer provided to separate the first conductivity-type well from the semiconductor substrate, a first conductivity-type diffusion region including an impurity concentration lower than that of the first conductivity-type well, and means for controlling a depletion layer in the first conductivity-type diffusion region.

A semiconductor device of a second exemplary aspect includes a semiconductor substrate of a first conductivity-type, a buried diffusion layer of a second conductivity-type formed in the semiconductor substrate, a first well of the second conductivity-type having a bottom portion in contact with a top portion of the buried diffusion layer, the first well having an annular shape in a planar view, and a second well of the first conductivity-type formed to be surrounded by the first well. The semiconductor device further includes a diffusion region formed between a first portion of the second well and a second portion of the second well, the diffusion region having an impurity concentration lower than that of the second well, so that a depletion layer formed in the diffusion region can be provided, a transistor formed on the second well to function as an ESD (electro-static discharge) protection element, and an external terminal connected to a drain of the N channel transistor.

The exemplary aspects make it possible to increase the resistance value of the parasitic resistance by the foregoing configuration. As a result, the exemplary aspects make it possible to cause a snapback quickly by a small electric current. In other words, the exemplary aspects can increase the ESD breakdown resistance. In addition, the exemplary aspects can increase the resistance value of the parasitic resistance. This makes it possible to also reduce the size of the parasitic resistance. Furthermore, the second conductivity-type well and the second conductivity-type buried diffusion layer are arranged to isolate the first conductivity-type wells. For this reason, the exemplary aspects can prevent an electric potential from fluctuating in the substrate in which the internal circuit is formed, even if an electric potential rises in the first conductivity-type wells. Accordingly, the exemplary aspects can eliminate a latch up which would otherwise occur due to operation of the protection element, and can provide the distance between the protection element and the internal element shorter than in related cases.

The present invention brings about an excellent effect of providing a semiconductor device which makes it possible to achieve miniaturization of its elements and an increase in the ESD breakdown resistance.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a schematic plan view of an ESD protection element according to an exemplary embodiment 1.

FIG. 2 is a cross-sectional view taken along the II-II line of FIG. 1.

FIG. 3 is an equivalent circuit diagram of the ESD protection element according to the exemplary embodiment 1.

FIG. 4 is a diagram showing a snapback characteristic of an N channel protection transistor according to the exemplary embodiment 1.

FIG. 5 is a schematic plan view of an ESD protection element according to an exemplary embodiment 2.

FIG. 6 is a cross-sectional view taken along the VI-VI line of FIG. 5.

FIG. 7 is a schematic plan view of an ESD protection element according to an exemplary embodiment 3.

FIG. 8 is a cross-sectional view taken along the VIII-VIII line of FIG. 7.

FIG. 9 is a schematic cross-sectional view of an ESD protection element according to an exemplary embodiment 4.

FIGS. 10A and 10B are circuit diagrams showing examples of a bias circuit applicable to the exemplary embodiments.

FIG. 11 is a cross-sectional view showing an ESD protection element pertaining to Patent Document 1.

FIG. 12 is a cross-sectional view showing an ESD protection element pertaining to Patent Document 2.

### DETAILED DESCRIPTION OF THE EXEMPLARY EMBODIMENTS

### Exemplary Embodiment 1

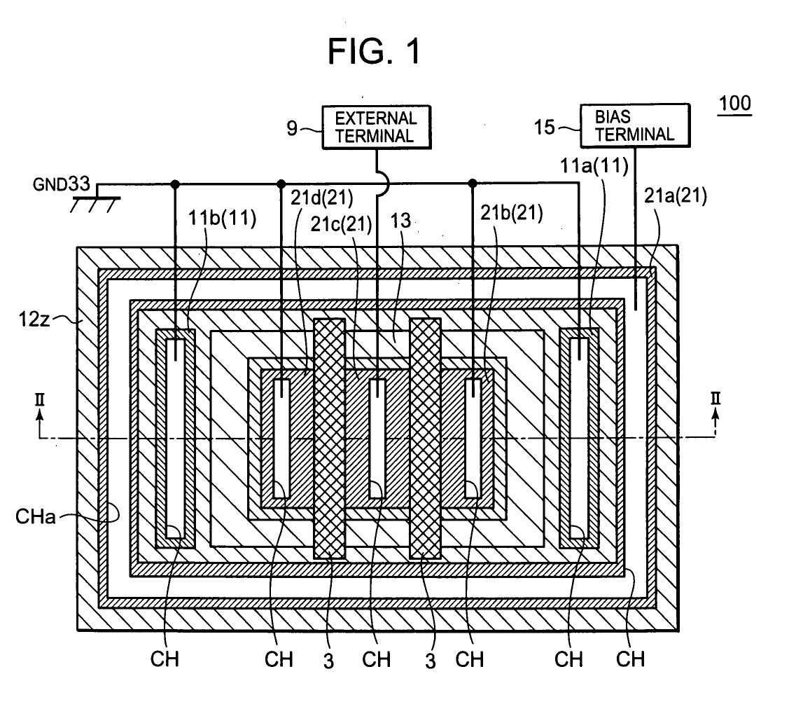

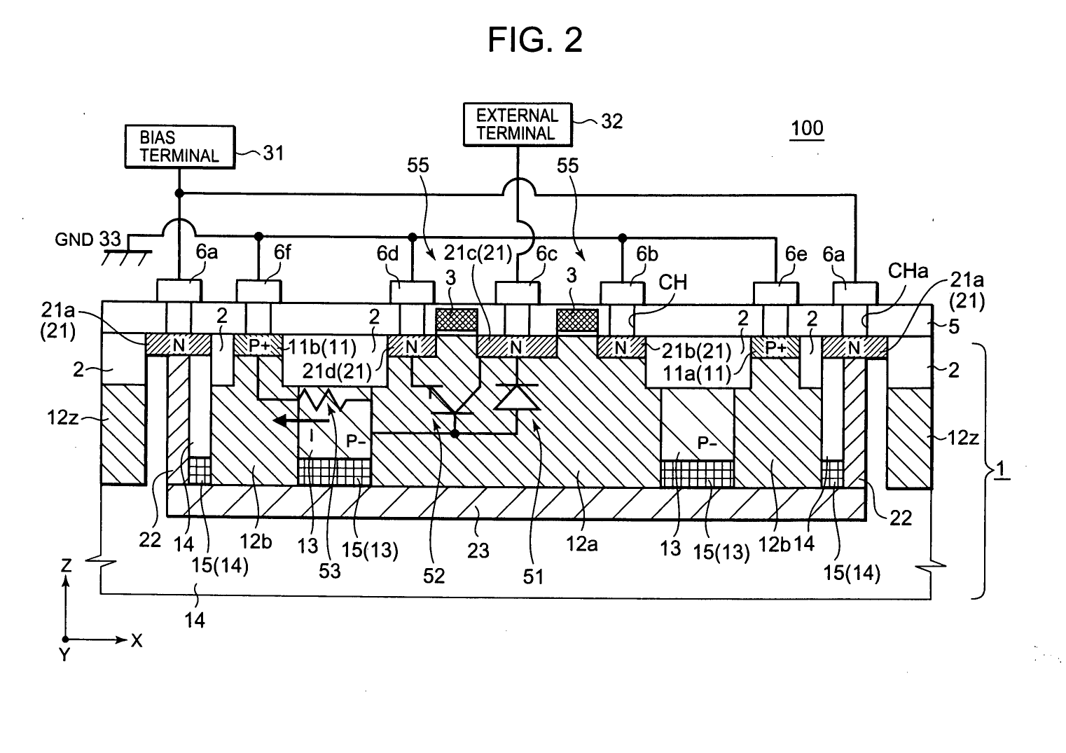

FIG. 1 shows a schematic plan view of a semiconductor device 100 which includes an ESD protection element according to exemplary embodiment 1. FIG. 2 shows a cross-sectional view of the semiconductor device 100 taken along the II-II line of FIG. 1. Note that illustrations of a field oxide film 2, an interlayer dielectric 5 and the like are omitted from FIG. 1 for the sake of explanatory convenience whereas positions of contact holes are illustrated in FIG. 1. The same is the case with the plan views coming after FIG. 1.

As shown in FIG. 2, the semiconductor device 100 includes a P type semiconductor substrate 1 (hereinafter referred to as a “substrate 1” as well) configured to function as a first conductivity-type semiconductor substrate. As shown in FIGS. 1 and 2, formed in the substrate 1 are: P⁺ type semiconductor diffusion regions (hereinafter referred to as “P⁺ type diffusion regions”) 11 (11a, 11b) as P type regions; P⁺ type wells 12 (12a, 12b, 12z) configured to function as first conductivity-type wells; a P⁻ semiconductor diffusion region (hereinafter referred to as a “P⁻ type diffusion region”) 13 configured to function as a first conductivity-type low-concentration diffusion region; and a P⁻ type substrate region 14 configured to, similarly, function as a first conductivity-type low-concentration diffusion region.

Also formed in the substrate 1 are: N type semiconductor diffusion regions (hereinafter referred to as “N type diffusion regions”) 21 (21a to 21d) as N regions; an N type well 22 configured to function as a second conductivity-type well; and an N type buried diffusion layer 23 configured to function as a second conductivity-type buried diffusion layer. Here, the P⁻ type substrate region 14 is a region whose concentration is equal to that of a region formed outside the N type well 22 and the N type buried diffusion layer 23. The P⁻ type diffusion region 13 is a region whose impurity concentration is higher than that of the P⁻ type substrate region 14, and whose impurity concentration is lower than that of the first conductivity-type wells 12. Meanwhile, gates 3, gate oxide films 4, an interlayer dielectric 5, upper-layer interconnections 6 (6a to 6f), contact holes CH and the like are formed on the substrate 1.

As shown in FIG. 1, the multiple N type diffusion regions 21 are formed. One of them is an N type diffusion region 21a which is shaped like a frame body (a ring) in a planar view. Three island-shaped N type diffusion regions 21b to 21d are formed within a region surrounded by the N type diffusion region 21a. The three N type diffusion regions 21b to 21d extend in the Y-axis direction in FIG. 1, and are arranged to be spaced away from one another.

Two P⁺ type diffusion regions 11a, 11b extend in the Y-axis direction in FIG. 1, and are formed within the region surrounded by the N type diffusion region 21a. The P⁺ type diffusion region 11a is arranged inside the N type diffusion region 21a, but outside the N type diffusion region 21b, with the field oxide film 2 interposed between the P⁺ type diffusion region 11a and the N type diffusion region 21a, and with the field oxide film 2 interposed between the P⁺ type diffusion region 11a and the N type diffusion region 21b. Similarly, the P⁺ type diffusion region 11b is arranged inside the N type diffusion region 21a, but outside the N type diffusion region 21b, with the field oxide film 2 interposed between the P⁺ type diffusion region 11b and the N type diffusion region 21a, and with the field oxide film 2 interposed between the P⁺ type diffusion region 11b and the N type diffusion region 21d.

The N type well 22 is formed in a layer immediately under the N type diffusion region 21a shaped like the frame body (see FIG. 2). A region in which the N type well 22 is formed is arranged in such a way as to overlap a contact hole CHa shaped like a frame body in a planar view as shown in FIG. 1, the size of the region is almost equal to that of the contact hole CHa. The depth of the N type well 22 extends in the Z-axis direction in FIG. 2 in such a way as to be almost equal to those of the P type wells 12. Note that the contact hole CHa and the N well 22 may be different in size from each other although the foregoing descriptions have been provided for the case where the shapes of the contact hole CHa and the N well 22 are almost equal to each other.

The N type buried diffusion layer 23 is formed under the N type well 22 in such a way as to abut on the N type well 22. The N type buried diffusion layer 23 has a rectangular shape, which almost coincides with the external circumference of the N type well 22 in a planar view.

The N type diffusion region 21a shaped like the frame body is electrically connected to the upper layer interconnection 6a through the contact hole CHa which is formed in the interlayer dielectric 5. The upper layer interconnection 6a is connected to a bias terminal 31. A positive bias potential is supplied to the bias terminal 31. In other words, the N type well 22 and the N type buried diffusion layer 23 are supplied region 21, the contact hole CH and the interconnection layer 6a. Note that when a negative power supply is used, zero volt bias potential may be supplied to the bias terminal 31 instead of the positive potential.

The first P type well 12a and the second P type well 12b are spaced away from each other, and are formed within a region which is separated from the P⁻ type substrate region 14 by the N type well 22 and the N type buried diffusion layer 23. The second P type well 12b is shaped like a frame body (a ring) in a planar view (see FIG. 1), and is arranged to oppose the N type well 22 with the P⁻ type substrate region 14 interposed in between. The P type well 12a has a rectangular shape (see FIG. 1), and is arranged to oppose the second P type well 12b with the P⁻ type diffusion region 13 interposed in between.

The P⁻ type diffusion region 13 is shaped like a frame body in a planar view within the region surrounded by the N type diffusion region 21a. The P⁻ type diffusion region 13 is placed in a way that the N type diffusion region 21a and the second P type well 12b are arranged on the two sides of the P⁻ type diffusion region 13, respectively. In other words, the first P type well 12a and the second P type well 12b are arranged to oppose each other with the first P⁻ type diffusion region 13a interposed in between, that is, predetermined spaces in between. The P⁻ type diffusion region 13 is a region whose impurity concentration is lower than those of the first P type 12a and the second P type well 12b. Specifically, used is a region whose resistance value is more than tens of times as large as those of the first P type 12a and the second P type well 12b.

The three N type diffusion regions 21b, 21c, 21d are formed in an upper layer of the first P type well 12a. The N type diffusion regions 21b, 21d correspond to the sources of N channel protection transistors, respectively. The remaining N type diffusion region 21c, which is arranged between the N type diffusion regions 21b, 21d, corresponds to the drains of the respective N channel protection transistors. The gates 3 includes gate oxide film 4 and a polysilicon, and are formed on the upper layer of the substrate 1 located between the N type diffusion region 21c and the N type diffusion regions 21b, 21d. In the other words, the two N channel protection transistors 55 are formed within the first P type well 12a. The P⁺ type diffusion regions 11a, 11b are respectively arranged at the two ends, in the X axis direction in FIG. 1, of the two N channel protection transistors 55.

The upper layer interconnections 6 are connected to the diffusion regions through the respective contact holes CH. The field oxide film 2 is formed in interstices between the P⁺ type diffusion regions 11 and the N type diffusion regions 21b, 21d, as well as on the P− type diffusion region 13. The N type diffusion region 21c acts as the drain region for the N channel protection transistors 55, and is connected to an external terminal 32 through the contact hole CH and the upper layer interconnection 6c. In addition, the N type diffusion regions 21b, 21d acts as the source regions for the N channel protection transistors 55, and are connected to the GND 33 through the upper layer interconnections 6b, 6d, respectively. Similarly, the P⁺ diffusion regions 11 are connected to the GND 33 through the upper layer interconnections 6e, 6f, respectively.

As shown in FIG. 2, a parasitic diode 51, a parasitic NPN transistor 52 and a parasitic resistance 53 are formed in the semiconductor device 100 under a predetermined condition. The parasitic NPN transistor 52 includes the N type diffusion region 21d as its emitter; the first P type well 12a as its base; and the N type diffusion region 21c as its collector. The parasitic resistance 53 is formed between the base and the P⁺ type diffusion layers 11. The parasitic resistance 53 is formed by the first P type well 12a, the second P type well 12b, and the P⁻ type diffusion region 13 which is located under the field oxide film 2. The parasitic diode 51 is formed between the first P type well 12a and the N type diffusion layer 21c.

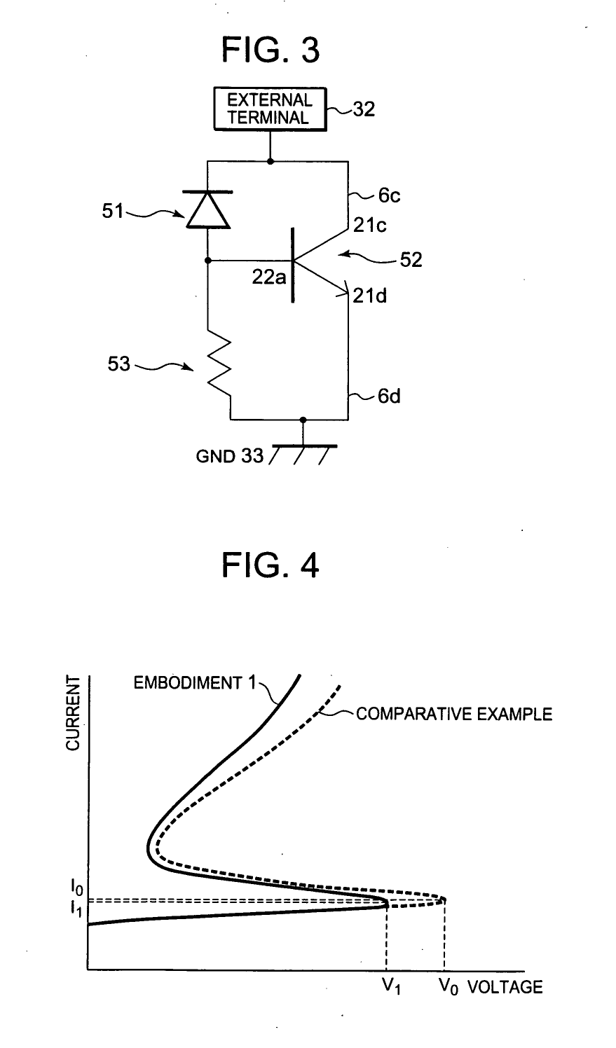

FIG. 3 is an equivalent circuit diagram of the parasitic NPN transistor 52 which is configured to operate to protect the internal circuit (not illustrated) from electro-static destruction when an ESD surge is applied to the external terminal 32. FIG. 4 shows a snapback characteristic (indicated by the solid line) of one N channel protection transistor 55 configured to function as the protection element according to the exemplary embodiment 1, and a snapback characteristic (indicated by the broken line) of an N channel protection transistor according to a comparative example. The configuration of the comparative example will be described later.

In the case of the semiconductor device 100 configured as described above, when a positive ESD surge is applied to the external terminal 32, the ESD surge is transmitted to the N type diffusion region 21c through the upper layer interconnection 6c, and the parasitic diode 51 accordingly breaks down. At this time, an electric current I flows to the parasitic resistance 53 which is formed by the first P type well 12a, the second P type well 12b and the p⁻ type diffusion region 13. Thereafter, the ESD surge passes through the parasitic resistance 53, and then flows to the GND. When the electric current flows due to the ESD surge, a voltage occurs in the parasitic resistance 53. When the base voltage of the parasitic transistor 52 exceeds a threshold voltage VBE (for instance, 0.7V), the electric current flows through the parasitic NPN transistor 52. This suppresses the collector voltage in a way that the collector voltage is not higher than a certain value. Thereby, the N channel protection transistor 55, which is the protection element, prevents the ESD surge from being transmitted into the internal circuit (not illustrated), and accordingly protects the internal circuit.

In other words, the parasitic NPN transistor 52 turns on when a value obtained by multiplying the electric current I, which flows through the parasitic resistance 53, by a resistance value (V) of the parasitic resistance 53 becomes larger than the threshold voltage VBE of the NPN transistor 52. This puts the NPN transistor 52 in a snapback state. A voltage applied immediately before the parasitic NPN transistor 52 enters into the snapback state, denoted by V₁ in FIG. 4. When the parasitic NPN transistor 52 turns on and thus enters into the snapback state, the voltage between the emitter and the collector drops quickly, and subsequently reduces to a saturation voltage of the parasitic NPN transistor 52. The internal circuit is protected by use of this snapback phenomenon.

As described above, the resistance value of the P⁻ type diffusion layer 13 constituting the parasitic resistance 53 is more than tens of times as large as the resistance values of the first P type well 12a and the second P type well 12b. In addition, exemplary embodiment 1 provides depletion layer controlling means for a depletion layer 15 in the P− type diffusion region 13. Specifically, a region corresponding to the depletion layer 15 in the P− type diffusion region 13 is controlled by supplying a bias potential to the region through the N type diffusion region 21a, the N type well 22 and the N type buried diffusion layer 23. The control of the region corresponding to the depletion layer 15 makes it possible to set the resistance value of the parasitic resistance 53 larger than that of Patent Document 2 above.

This makes a value, which is obtained by multiplying “the electric current I” by “the resistance value of the parasitic resistance 53,” larger than the threshold voltage VBE (V) of the parasitic NPN transistor 52. Accordingly, the current value of the electric current I which causes the parasitic NPN transistor 52 to enter into the snapback state can be made smaller than that of Patent Document 2 described above.

In recent years, as described above, as elements included in a semiconductor integrated circuit have become progressively smaller, the ESD breakdown resistance has become lower. With this taken into consideration, a strong demand is placed for a semiconductor device which makes it possible to achieve miniaturization of its elements and an increase in the ESD breakdown resistance. Because of the foregoing configuration, exemplary embodiment 1 makes it possible to effectively make the resistance value of the parasitic resistance 53 larger than that of Patent Document 2 described above. Accordingly, exemplary embodiment 1 makes it possible to increase the ESD breakdown resistance even in a case where the size of the parasitic resistance 53 is reduced in conjunction with the miniaturization of the elements.

Descriptions will be provided for snapback characteristics by use of FIG. 4. The configuration for the comparative example indicated by the broken line in FIG. 4 is the same as the configuration for exemplary embodiment 1, except that the configuration for the comparative example includes neither the N type well 22 nor the N type buried diffusion layer 23. The configuration for exemplary embodiment 1 includes the depletion layer controlling means for controlling the depletion layer in the P⁻ type diffusion layer 13 as the parasitic resistance 53. For this reason, the exemplary embodiment 1 is capable of making the resistance value of the parasitic resistance 53 larger than that of the comparative example. In other words, the resistance value of the parasitic resistance according to the exemplary embodiment 1 is larger than the resistance value of the parasitic resistance according to the comparative example. Here, the threshold voltage VBE of the parasitic NPN transistor according to the exemplary embodiment 1 is equal that of the comparative example. Accordingly, the exemplary embodiment 1 is capable of making the value of the electric current I, which causes a value obtained by multiplying the “electric current I” by the “resistance value of the parasitic resistance 53” to exceed the threshold voltage VBE (for instance, 0.7V) of the parasitic NPN transistor 52, smaller than that of the comparative example.

This satisfies the following relationships, as shown in FIG. 4.

The electric current I₁ immediately before the snapback according to the exemplary embodiment 1 is smaller than the electric current I₀ immediately before the snapback according to the comparative example.

The voltage V₁ immediately before the snapback according to the exemplary embodiment 1 is smaller than the voltage V₀ immediately before the snapback according to the comparative example.

In other words, the exemplary embodiment 1 is capable of setting the value of the parasitic resistance larger by including the first conductivity-type well 12a, 12b, the P− type diffusion region 13 and the depletion layer controlling means as the resistance value controlling means for the parasitic resistance 53. As a consequence, the exemplary embodiment 1 is capable of putting the parasitic NPN transistor 52 into the snapback state more quickly than the comparative example. In addition, the exemplary embodiment 1 is capable of holding lower the voltage which is applied to the internal circuit. Accordingly, the ESD protection element according to the exemplary embodiment 1 is capable of increasing the ESD breakdown resistance although the area of the ESD protection element according to the exemplary embodiment 1 is equal to or smaller than that of the comparative example.

As described above, as the resistance value of the parasitic resistance 53 becomes smaller, the electric current I which puts the parasitic NPN transistor 52 into the snapback state becomes larger, and the ESD breakdown resistance accordingly becomes smaller. Conversely, in a case where the resistance value of the parasitic resistance 53 becomes excessively larger, the value of the voltage immediately before the snapback state becomes smaller than a voltage needed to operate the LSI. This makes it likely that the LSI may malfunction. The exemplary embodiment 1 is capable of controlling the region corresponding to the depletion layer 15, because the exemplary embodiment 1 controls the voltage which is applied to the bias terminal 32. As a consequence, the exemplary embodiment 1 is capable of optimizing the resistance value of the parasitic resistance 53.

Furthermore, the first P type well 12a and the second P type well 12b are separated from the internal circuit (not illustrated) by the N type well 22 and the N type buried diffusion layer 23 in the substrate 1. Therefore, the exemplary embodiment 1 prevents the fluctuation of the electric potential of the substrate in which the internal circuit is formed, even though the electric potentials of the first P type well 12a and the second P type well 12b as the independent wells rise while the protection element is in operation, respectively. Accordingly, the exemplary embodiment 1 is capable of preventing a latch up which would otherwise occur due to the operation of the protection element, and thus capable of making the distance between the protection element and the internal circuit shorter than in conventional cases. In other words, the exemplary embodiment 1 is capable of saving the space.

Moreover, even if a negative power supply (minus or negative power supply) is used as the GND terminal 33 shown in FIGS. 1 to 3, the exemplary embodiment 1 makes the N channel protection transistor 55 capable of obtaining the same effect as the exemplary embodiment 1 which is otherwise configured as described above. That is because the first P type well 12a and the second P type well 12b constituting the N channel protection transistor 55 are separated from the P⁻ type substrate region 14 by the N type well 22 and the N type buried diffusion layer 23. For this reason, the exemplary embodiment 1 enables the N channel protection transistor 55 to be used to protect the semiconductor device when the negative power supply is used. Additionally, the exemplary embodiment 1 makes the N channel protection transistor 55 suitable for being used with a high voltage which is not lower than 10V since the P⁻ type substrate region 14 is provided between the N type well 22 and the second P type well 12b.

In the case of the exemplary embodiment 1, note that instead of the P⁻ type low-concentration diffusion region 13, the P⁻ type substrate region 14 may be used at the position where the P⁻ type low-concentration diffusion region 13 is placed. In addition, instead of the P⁻ type substrate region 14, the P⁻ type substrate region 13 may be formed between the N type well 22 and the P type well 12b. The two cases can be implemented by only changing mask patterns for forming the P type wells, without requiring any special manufacturing step additionally. Furthermore, although the exemplary embodiment 1 is shown as the case where the semiconductor device includes the minimal two gates, the semiconductor device may include three or more gates instead. Moreover, it is not essential to connect the N type well 22 and the N type buried diffusion layer 23 to the bias terminal 33. Instead, the semiconductor device according to the exemplary embodiment 1 may include means for supplying the bias potential to the N type well 22 and the N type buried diffusion layer 23 from the internal circuit.

### Exemplary Embodiment 2

Next, descriptions will be provided for an example of a semiconductor device including an ESD protection element which is different from the ESD protection element according to the exemplary embodiment 1. The semiconductor device according to an exemplary embodiment 2 is the same as the semiconductor device according to the exemplary embodiment 1 in terms of the basic configuration and the manufacturing method, except for the following point. Specifically, what is different is that, the first P type well and the second P type well are connected together by connectors (other P type wells) in a case of the P type wells according to the exemplary embodiment 2 whereas the first P type well 12a and the second P type well 12b constituting the P type wells 12 according to the exemplary embodiment 1 are completely separated from each other with the P⁻ type diffusion region 13 interposed in between. In other words, the P⁻ type diffusion region 13 according to the exemplary embodiment 2 is divided into two sections by the above-mentioned connectors, whereas the P⁻ type diffusion region 13 according to the exemplary embodiment 1 is shaped like the frame body.

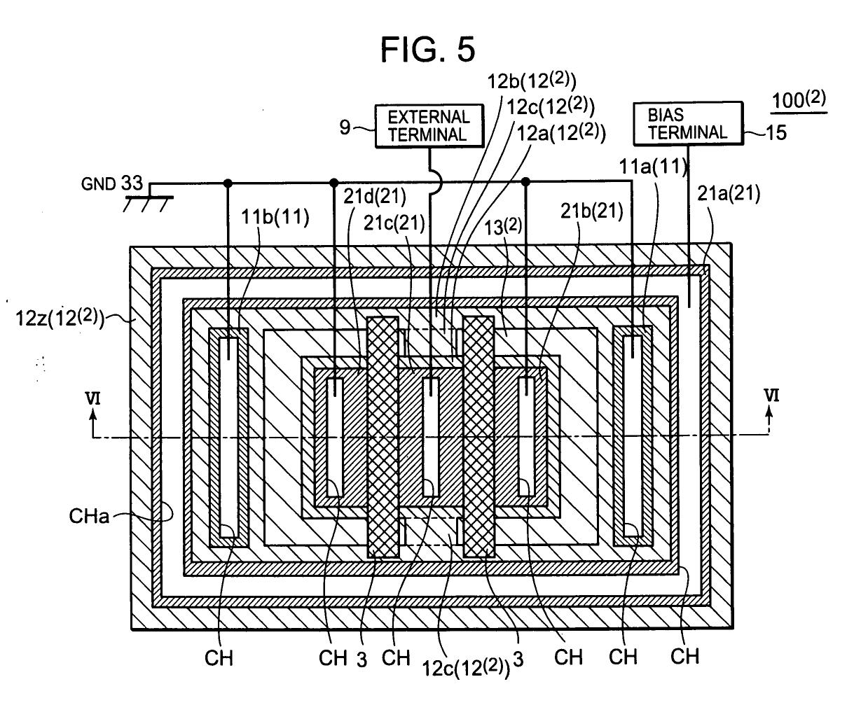

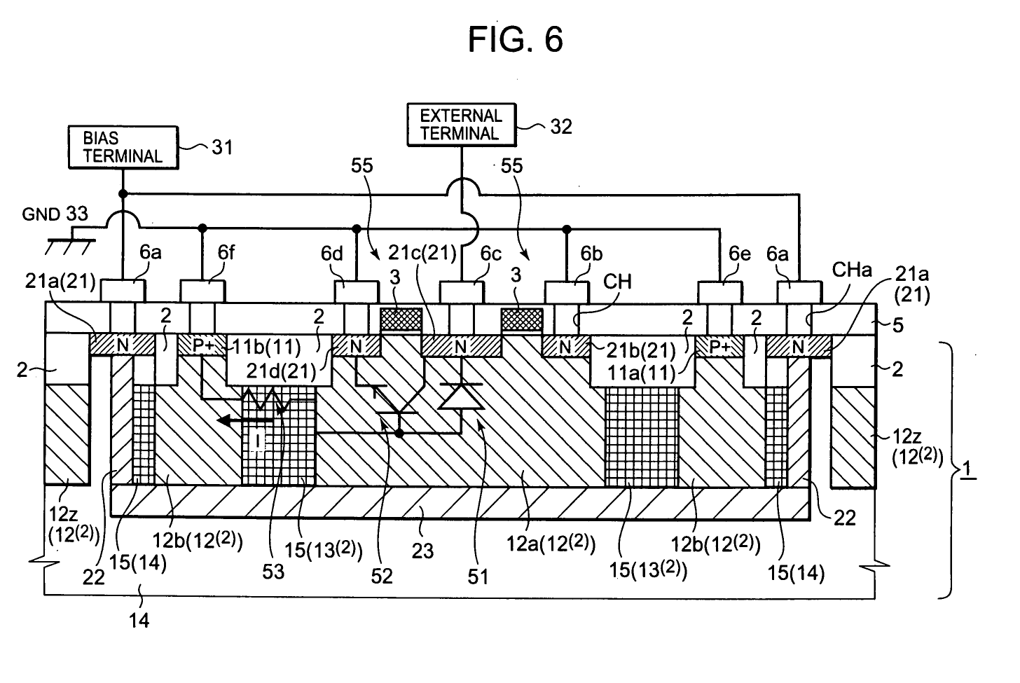

FIG. 5 shows a schematic plan view of the semiconductor device 100⁽²⁾ which includes the ESD protection element according to the exemplary embodiment 2. FIG. 6 shows a cross-sectional view taken along the VI-VI line of FIG. 5.

In the case of the exemplary embodiment 2, the first P type well 12a and the second P type well 12b are connected together by third P type wells 12c configured to function as the connectors. In other words, the P type wells 12⁽²⁾ arranged in the region separated by the N type well 22 and the N type buried diffusion layer 23 are formed by the first P type well 12a, the second P type well 12b and the third P type wells 12c.

The two third P type wells 12c are placed in a way that the first P type well 12a and the second P type well 12b are connected together at two positions which are situated in a lengthwise direction of the N type diffusion region 21c. In other words, each third P type well 12c is placed in a way that the first P type well 12a and the second P type well 12b are connected together at central areas of the lines of the first P type well 12a and the second P type well 12b, the lines extending in a direction perpendicular to a direction of the gate length.

The P− type diffusion region 13⁽²⁾ is divided into two sections by the third P type wells 12c. Accordingly, the P⁻ type diffusion region 13⁽²⁾ is almost shaped like a modified side ways U and its left-to-right reversal in a planar view. The modified side ways U may have sharp corners as shown in FIG. 3. Like the exemplary embodiment 1, the P− type diffusion region 13⁽²⁾ is a region whose impurity concentration is lower than those of the first P type well 12a and the second P type well 12b. Specifically, used is a region whose impurity concentration is more than tens of times as large as those of the first P type well 12a and the second P type well 12b.

While the semiconductor device 100⁽²⁾ according to the exemplary embodiment 2 is in normal operation, if the N type well 22 and the N type buried diffusion layer 23 are biased with a high potential, then a depletion layer 15⁽²⁾ formed in the P⁻ type diffusion region 13⁽²⁾ extends until it comes in contact with the field oxide film 2 as shown in FIG. 6. In this case, because the third P type wells 12c are placed there, it is possible to prevent a malfunction which would occur if the first P type well 12a and the second P type well 12b were separated from each other and thus brought into a floating state. Therefore, each of the P⁺ type diffusion region 11a, 11b to which the parasitic resistance 53 is connected can be spaced away from the third P type wells 12c configured to function as the connectors, by a maximum distance. As a consequence, it is possible to prevent the first P type well 12a and the second P type well 12b from being brought into a floating state while securing a functional region (including the first P type well 12a, the second P type well 12b and the P− type diffusion region 13) configured to control the resistance value of the parasitic resistance 53.

The exemplary embodiment 2 is capable of obtaining the same effect as the exemplary embodiment 1 is. In addition, because the third P type wells 12c are placed there, the exemplary embodiment 2 can be suitably applied particularly to a semiconductor device whose power supply potential is high. Furthermore, the exemplary embodiment 2 has an advantage that the third P type wells 12c can be formed by only changing mask patterns for forming the P type wells, without requiring any special manufacturing step additionally.

### Exemplary Embodiment 3

A semiconductor device according to an exemplary embodiment 3 is the same as the semiconductor device according to the exemplary embodiment 2 in terms of the basic configuration and the manufacturing method, except for the following point. Specifically, what is different is that the N type diffusion region 21a according to the exemplary embodiment 3 is connected to an external terminal 32⁽³⁾ through the upper layer interconnection 6a connected to a diode, which is further connected to the external terminal 32⁽³⁾, whereas the N type diffusion region 21a according to the exemplary embodiment 2 is connected to the bias terminal 15 through the upper layer interconnection 6a.

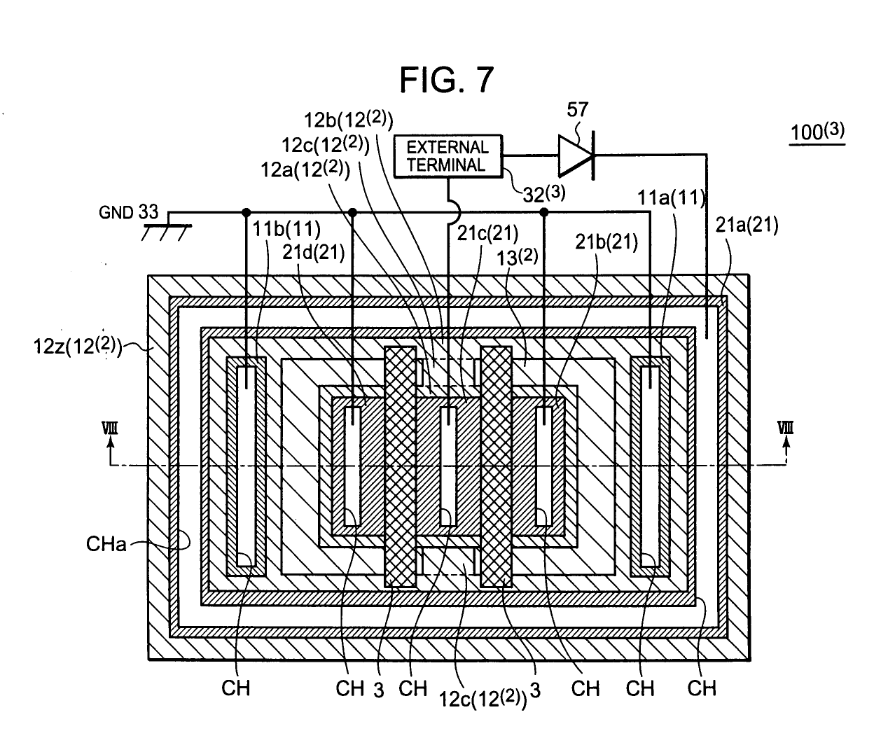

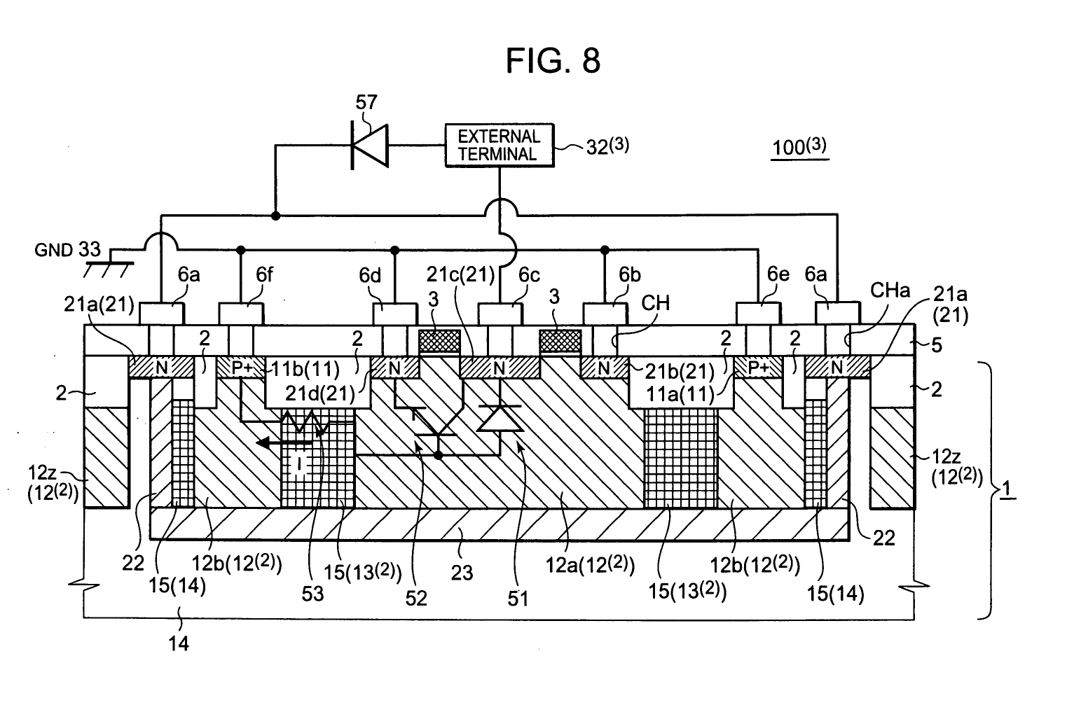

FIG. 7 shows a schematic plan view of the semiconductor device 100⁽³⁾ which includes an ESD protection element according to the exemplary embodiment 3. FIG. 8 shows a cross-sectional view taken along the VIII-VIII line of FIG. 7.

The N type diffusion region 21a shaped like the frame body is electrically connected to the upper layer interconnection 6a through the contact hole CHa which is formed in the interlayer dielectric 5. As shown in FIG. 7, the upper layer interconnection 6a is connected to a diode 57. The diode 57 is connected to the external terminal 32⁽³⁾.

When a positive ESD surge is applied to the external terminal 32⁽³⁾, a forward potential is applied to the diode 57. For this reason, a low bias from the positive ESD surge is applied to the N type well 22 and the N type buried diffusion layer 23 via the VBE of the diode 57. This makes the depletion layer 15 extend from the N type buried diffusion layer 23, in a region corresponding to the P⁻ type diffusion region 13. Because no electric current flows through the depletion layer 15, the path through which the electric current I flows to the parasitic resistance 53 is only a narrow interstice between the depletion layer 15 and the field oxide film 2. This makes the resistance value of the parasitic resistance 53 larger than that of each of the related and comparative examples.

The configuration provides a large ESD breakdown resistance for the protection element according to the exemplary embodiment 3, as in the case of exemplary embodiment described above. Furthermore, even if a negative power supply (minus power supply) is used as the GND terminal 33, it is possible to obtain the same effect as the exemplary embodiment 3 which is otherwise configured as described above. That is because the second P type well 12b is separated from the P⁻ type substrate region 14 by the N type well 22 and the N type buried diffusion layer 23. In other words, the exemplary embodiment 3 enables the protection element to be used as a protection against use of the negative power supply. Moreover, it is possible to obtain the same effect as the exemplary embodiment 2, because the third P type wells 12c, configured to function as the connectors, are provided. Furthermore, the exemplary embodiment 3 enables the bias potential to be controlled by the formed diode 57.

### Exemplary Embodiment 4

A semiconductor device according to an exemplary embodiment 4 is the same as the semiconductor device according to the exemplary embodiment 1 in terms of the basic configuration and the manufacturing method, except for the following point. Specifically, what is different is that the exemplary embodiment 4 causes the N type well 22 and the second P type well 12b to abut each other whereas the exemplary embodiment 1 places the P⁻ type substrate region 14 between the N type well 22 and the second P type well 12b. In other words, the difference is that the exemplary embodiment 4 places the second P type well at the position at which the exemplary embodiment 1 places the P⁻ type substrate region 14.

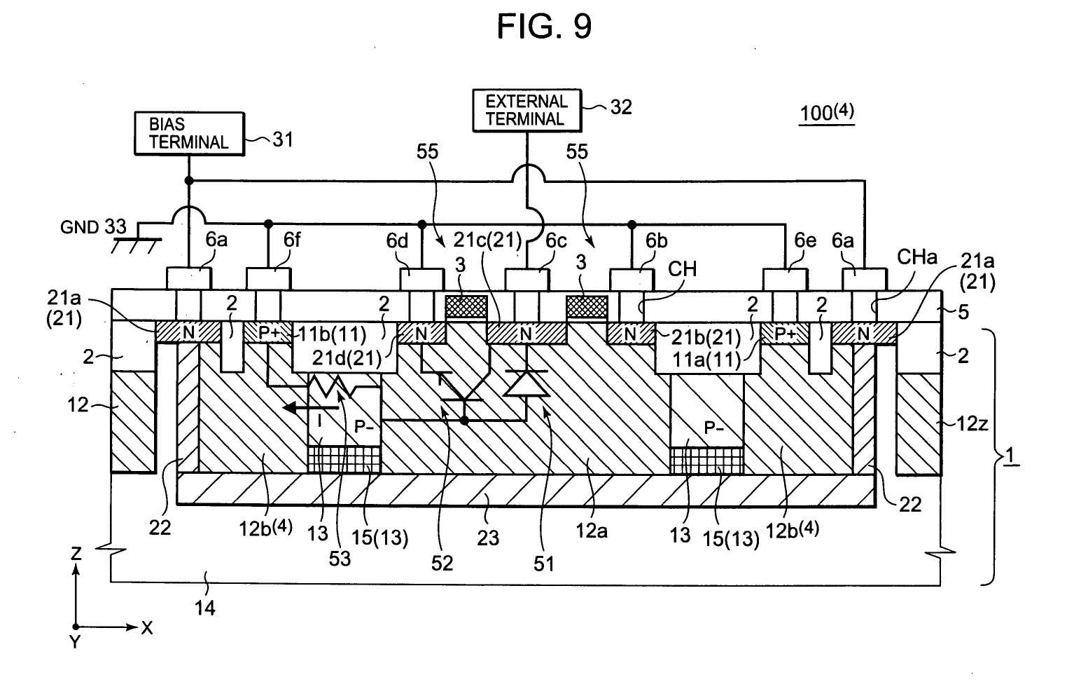

FIG. 9 shows a schematic plan view of a semiconductor device 100⁽⁴⁾ which includes an ESD protection element according to the exemplary embodiment 4. The position of the cross-section of the semiconductor device corresponds to the II-II line of FIG. 1.

The exemplary embodiment 4 is suitable for a low voltage use, approximately several volts. The exemplary embodiment 4 does not place the P⁻ type substrate region 14 in the interstice between the N type well 22 and the second P type well 12b⁽⁴⁾, but instead places the second P type well 12b⁽⁴⁾ in the interstice. Even with this configuration, the exemplary embodiment 4 is capable of obtaining the same effect as the exemplary embodiment 1.

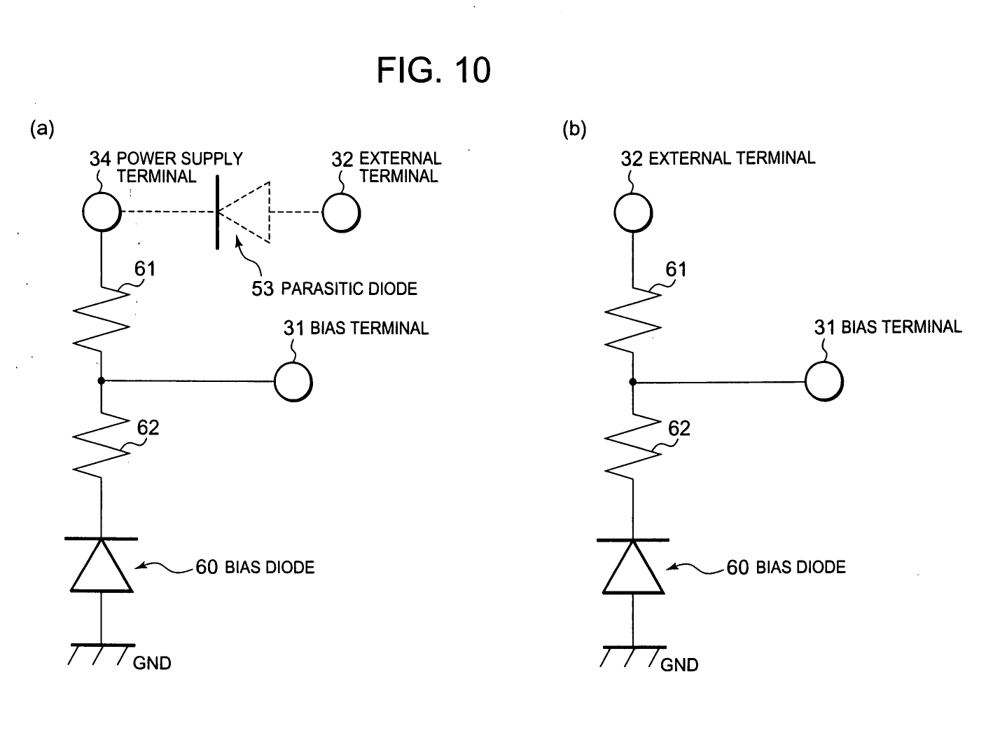

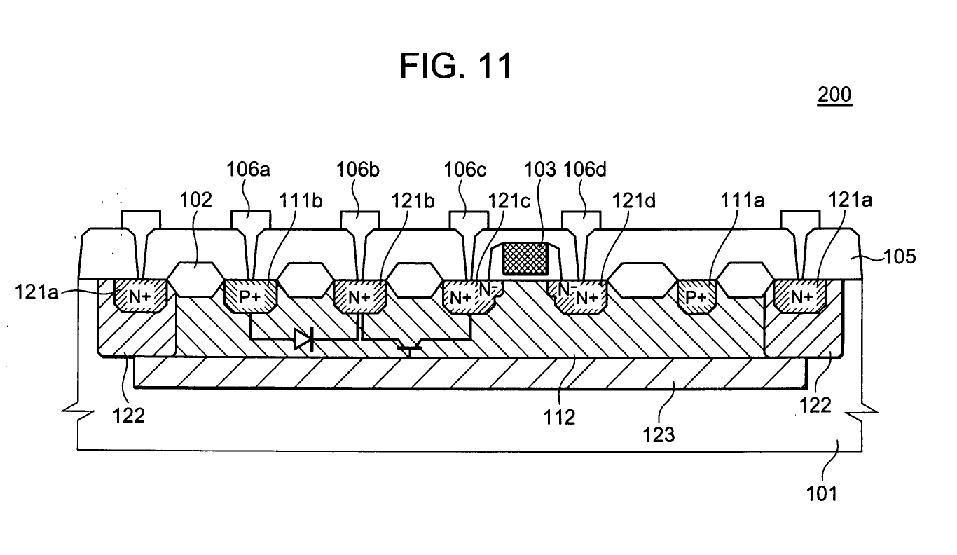

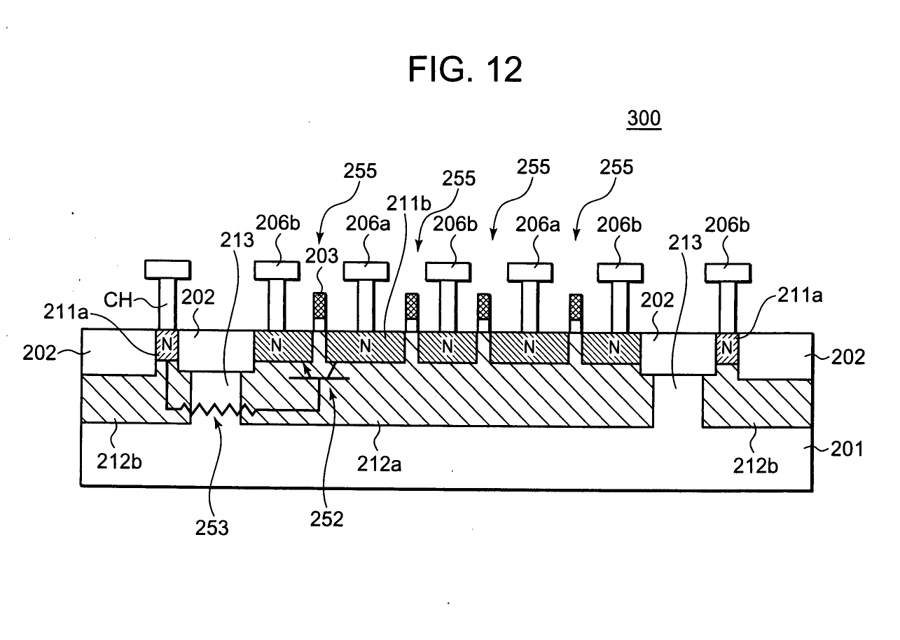

The exemplary embodiments 1 to 4 have been described based on the examples where the first conductivity type is P type whereas the second conductivity type is N type. However, note that even if the first conductivity type is N type whereas the second conductivity type is P type, the exemplary embodiments 1 to 4 are capable of obtaining the same effect. In addition, the depletion layer controlling means is not limited to the aspects respectively represented by the exemplary embodiments 1 to 4. Any means which can control the depletion layer 15 in the P⁻ type low-concentration diffusion region 13 can be used instead. The supply source of the bias potential is not limited to the aspects represented by the exemplary embodiments 1 to 4. For instance, the bias potential may be controlled by providing a bias circuit which includes a bias diode 60, a power supply terminal 34, a first resistance 61, a second resistance 62 and the like as shown in FIGS. 10A and 10B. Otherwise, a bias potential controlled by a bias circuit included in the internal circuit may be supplied.

Further, it is noted that Applicant's intent is to encompass equivalents of all claim elements, even if amended later during prosecution.

What is claimed is:

1. A semiconductor device including an ESD (electro-static discharge) protection element, the semiconductor device comprising:
a semiconductor substrate of a first conductivity-type;
a first conductivity-type well formed in the semiconductor substrate, the first conductivity-type well being a region where an N channel transistor configured to function as the ESD protection element is formed;
a second conductivity-type well and a second conductivity-type buried diffusion layer provided to separate the first conductivity-type well from the semiconductor substrate;
a first conductivity-type diffusion region including an impurity concentration lower than that of the first conductivity-type well and provided in contact with the first conductivity-type well; and
means for controlling a depletion layer in the first conductivity-type diffusion region.

2. A semiconductor device, comprising:
a semiconductor substrate of a first conductivity-type;
a buried diffusion layer of a second conductivity-type formed in the semiconductor substrate;
a first well of the second conductivity-type having a bottom portion in contact with a top portion of the buried diffusion layer, the first well having an annular shape in a planar view;
a second well of the first conductivity-type formed to be surrounded by the first well;
a diffusion region formed between a first portion of the second well and a second portion of the second well, the diffusion region having an impurity concentration lower than that of the second well, so that a depletion layer formed in the diffusion region can be provided;
a transistor formed on the second well to function as an ESD (electro-static discharge) protection element; and
an external terminal connected to a drain of the transistor.

3. The semiconductor device according to claim 2, further comprising:
a node which receives a bias potential to supply the bias potential to the diffusion region through the first well and the buried diffusion layer to control an amount of the depletion layer.

4. The semiconductor device according to claim 2, wherein the diffusion region is provided between the first and second wells.

5. The semiconductor device according to claim 2, wherein the diffusion region separates the first portion of the second well and the second portion of the second well.

6. The semiconductor device according to claim 2, further comprising:
a connection portion which connects the first portion of the second well and the second portion of the second well, the connection portion being a part of the second well.

7. The semiconductor device according to claim 6, wherein the connection portion connects with a substantially center portion of each of the first and second portions of the second well in a direction perpendicular to a gate length of the transistor.

8. The semiconductor device according to claim 3, further comprising:
a bias terminal connected to the node.

9. The semiconductor device according to claim 2, further comprising:
a diode provided between the external terminal and the first well.

10. A semiconductor device, comprising:
a semiconductor substrate of a first conductivity-type;
a buried diffusion layer of a second conductivity-type formed in the semiconductor substrate;
a first well of the second conductivity-type provided with the buried diffusion layer to provide an inside region separated from the semiconductor substrate;
a second well of the first conductivity-type formed in the inside region;
a first diffusion region formed between a first portion of the second well and a second portion of the second well, the first diffusion region formed on the buried diffusion layer so that a bias potential can be transferred to the first diffusion region via the first well and the buried diffusion layer, the first diffusion region having an impurity concentration lower than that of the second well, the first portion of the second well being supplied with a power source potential;
a second diffusion region of the first conductivity-type formed on the second portion of the second well;
an external terminal connected to the second diffusion region; and
a third diffusion region of the first conductivity-type formed on the second portion of the second well for receiving the power source potential.

11. The semiconductor device as claimed in claim 10, further comprising:
a connection portion of the first-conductivity type which connects the first portion of the second well to the second portion of the second well.

12. The semiconductor device as claimed in claim 10, further comprising:
a diode connected between the external terminal and the first well.

13. The semiconductor device as claimed in claim 10, further comprising:
a substrate region of the first conductivity-type formed between the first and second wells, the substrate region having an impurity concentration lower than that of the second well.

14. The semiconductor device as claimed in claim 10, wherein the first well is directly connected with the second well.
